(19) United States
(12) Patent Application Publication
(10) Pub. No.: US 2008/0105871 A1
(43) Pub. Date: May 8, 2008

(54) Thin film transistor array substrate having lightly doped amorphous silicon layer and method for fabricating same

(75) Inventors: Shuo-Ting Yan, Miao-Li (TW); Chien-Hsiung Chang, Miao-Li (TW); Yu-Hsiung Chang, Miao-Li (TW); Kai-Yuan Cheng, Miao-Li (TW); Tsau-Hua Hsieh, Miao-Li (TW); Chao-Yi Hung, Miao-Li (TW); Chao-Chih Lai, Miao-Li (TW)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 11/982,869

(22) Filed: Nov. 5, 2007

(30) Foreign Application Priority Data
Nov. 3, 2006 (TW) 95140732

(51) Int. Cl. H01L 29/167; H01L 21/84

(52) U.S. Cl. 257/58; 438/162; 257/E29.273; 257/E21.412

(57) ABSTRACT

An exemplary thin film transistor (TFT) array substrate (200) includes: a substrate (210), a gate electrode (220) disposed on the substrate, a gate insulating layer (230) disposed on the substrate having the gate electrode, a lightly doped amorphous silicon (a-Si) layer (241) disposed on the gate insulating layer, a first a-Si layer (242) disposed on the lightly doped a-Si layer, a source electrode (251) and a drain electrode (252) disposed on the gate insulating layer and the a-Si layer. The thin film transistor array substrate has a low leakage current.

### FIELD OF THE INVENTION

The present invention relates to thin film transistor (TFT) array substrates used in liquid crystal displays (LCDs) and methods for fabricating these substrates, and particularly to a TFT array substrate that includes a lightly doped amorphous silicon layer.

### GENERAL BACKGROUND

A typical liquid crystal display (LCD) is capable of displaying a clear and sharp image through thousands or even millions of pixels that make up the complete image. The LCD has thus been applied to various electronic equipment in which messages or pictures need to be displayed, such as mobile phones and notebook computers. A liquid crystal panel is a major component of the LCD, and generally includes a thin film transistor (TFT) array substrate, a color filter substrate opposite to the TFT array substrate, and a liquid crystal layer sandwiched between the two substrates. The TFT array substrate includes a plurality of TFTs used as switching elements.

Referring to FIG. 22, a typical TFT array substrate 100 is shown. The TFT array substrate 100 includes a substrate 110, a gate electrode 120 formed on the substrate 110, a gate insulating layer 130 formed on the substrate 110 having the gate electrode 120, an amorphous silicon (a-Si) layer 141 formed on the gate insulating layer 130, a heavily doped a-Si layer 142 formed on the a-Si layer 141, a source electrode 151 and a drain electrode 152 formed on the gate insulating layer 130 having the a-Si layer 141 and the heavily doped a-Si layer 142, and a passivation layer 160 formed on the gate insulating layer 130 having the source electrode 151 and the drain electrode 152.

Referring to FIG. 23, this is a flowchart summarizing a typical method for fabricating the TFT array substrate 100. For simplicity, the flowchart and the following description are couched in terms that relate to the part of the TFT array substrate 100 shown in FIG. 22. The method includes: step 101, forming a gate electrode; step 102, forming a gate insulating layer; step 103, forming an amorphous silicon (a-Si) layer; step 104, forming a heavily doped a-Si layer; step 105, forming source/drain electrodes; and step 106, forming a passivation layer.

In step 101, referring to FIG. 24, an insulating substrate 110 is provided. The substrate 110 is made from glass or quartz. A gate metal layer (not shown) is formed on the substrate 110 by a chemical vapor deposition (CVD) process or a physical vapor deposition (PVD) process. A first photo-resist layer (not shown) is formed on the gate metal layer. A photo-mask (not shown) and ultraviolet radiation (not shown) are provided to expose the first photo-resist layer. The exposed first photo-resist layer is developed, thereby forming a first photo-resist pattern. Using the first photo-resist pattern as a mask, the gate metal layer is etched, thereby forming the gate electrode 120. The residual first photo-resist layer is removed, and the substrate 110 is cleaned and dried.

In step 102, referring to FIG. 25, a gate insulating layer 120 is deposited on the substrate 110 having the gate electrode 120 by a CVD process. The gate insulating layer 120 is made from silicon nitride (SiNₓ) or silicon oxide (SiO₂).

In step 103, referring to FIG. 26, an a-Si layer 141 is deposited on the gate insulating layer 120 by a CVD process. The a-Si layer 141 corresponds to the gate electrode 120.

In step 104, referring to FIG. 27, a heavily doped a-Si layer 142 is formed on the a-Si layer 141 by a CVD process and a vapor phase doping process.

In step 105, referring to FIG. 28, a source/drain metal layer and a second photo-resist layer are sequentially formed on the gate insulating layer 130 having the a-Si layer 141 and the heavily doped a-Si layer 142. The second photo-resist layer is exposed by a second photo-mask, and then is developed, thereby forming a second photo-resist pattern. The source/drain metal layer is etched, thereby forming the source electrode 151 and the drain electrode 152. The residual second photo-resist pattern is then removed.

In step 106, referring to FIG. 29, a passivation layer 160 is formed on the insulating layer 130 having the source electrode 151 and the drain electrode 152.

When a positive voltage is applied between the gate electrode 120 and the source electrode 151, a strong electric field is generated in the gate insulating layer 130. The electric field repulses the holes and attracts the electrons in the a-Si layer 141 adjacent to the gate electrode 120. Thus, a conductive channel is generated. The source electrode 151 and the drain electrode 152 are electrically connected by the conductive channel, so that the TFT is turned on. Conversely, when a negative voltage is applied between the gate electrode 120 and the source electrode 151, the TFT is turned off. However, when the TFT is turned off, a leakage current still exists because of some residual holes in the a-Si layer 141, and the leakage current increases when the applied negative voltage increases. Therefore, the TFT array substrate 100 has impaired function, and the quality of images provided by the corresponding liquid crystal panel may be unsatisfactory.

What is needed, therefore, is a TFT array substrate that can overcome the above-described problems. What is also needed is a method for fabricating such TFT array substrate.

### SUMMARY

In one preferred embodiment, a thin film transistor array substrate includes a substrate, a gate electrode disposed on the substrate, a gate insulating layer disposed on the substrate having the gate electrode, a lightly doped amorphous silicon (a-Si) layer disposed on the gate insulating layer, a first a-Si layer disposed on the lightly doped a-Si layer, a source electrode and a drain electrode disposed on the gate insulating layer having the a-Si layer.

Other novel and advantages features will become more apparent from the following detailed description when taken in conjunction with the accompanying drawings.

### BRIEF DESCRIPTION OF THE DRAWINGS

FIG. 1 is a schematic, side cross-sectional view of part of a TFT array substrate according to a first embodiment of the present invention.

FIG. 2 is a flowchart summarizing a first exemplary method for fabricating the TFT array substrate of FIG. 1.

FIG. 3 is a schematic, side cross-sectional view relating to a step of providing a substrate and forming a gate electrode on the substrate according to the method of FIG. 2.

FIG. 4 is a schematic, side cross-sectional view relating to a step of forming a gate insulating layer on the substrate having the gate electrode according to the method of FIG. 2.

FIG. 5 is a schematic, side cross-sectional view relating to a step of forming a lightly doped a-Si layer on the gate insulating layer according to the method of FIG. 2.

FIG. 6 is a schematic, side cross-sectional view relating to a step of forming an a-Si layer on the lightly doped a-Si layer according to the method of FIG. 2.

FIG. 7 is a schematic, side cross-sectional view relating to a step of forming a heavily doped a-Si layer on the a-Si layer according to the method of FIG. 2.

FIG. 8 is a schematic, side cross-sectional view relating to a step of forming a source electrode and a drain electrode on the gate insulating layer and the heavily doped a-Si layer according to the method of FIG. 2.

FIG. 9 is a schematic, side cross-sectional view relating to a step of forming a passivation layer on the source/drain electrodes and the gate insulating layer according to the method of FIG. 2.

FIG. 10 is a schematic, side cross-sectional view of part of a TFT array substrate according to a second embodiment of the present invention.

FIG. 11 is a flowchart summarizing an exemplary method for fabricating the TFT array substrate of FIG. 10.

FIG. 12 is a schematic, side cross-sectional view relating to a step of providing a substrate and forming a gate electrode on the substrate according to the method of FIG. 11.

FIG. 13 is a schematic, side cross-sectional view relating to a step of forming a gate insulating layer on the substrate having the gate electrode according to the method of FIG. 11.

FIG. 14 is a schematic, side cross-sectional view relating to a step of forming a first a-Si layer on the gate insulating layer according to the method of FIG. 11.

FIG. 15 is a schematic, side cross-sectional view relating to a step of forming a lightly doped a-Si layer on the first a-Si layer according to the method of FIG. 11.

FIG. 16 is a schematic, side cross-sectional view relating to a step of forming a second a-Si layer on the lightly doped a-Si layer according to the method of FIG. 11.

FIG. 17 is a schematic, side cross-sectional view relating to a step of forming a heavily doped a-Si layer on the second a-Si layer according to the method of FIG. 11.

FIG. 18 is a schematic, side cross-sectional view relating to a step of forming a source electrode and a drain electrode on the gate insulating layer having the heavily doped a-Si layer according to the method of FIG. 11.

FIG. 19 is a schematic, side cross-sectional view relating to a step of forming a passivation layer on the source/drain electrodes and the gate insulating layer according to the method of FIG. 11.

FIG. 20 is a flowchart summarizing a second exemplary method for fabricating the TFT array substrate of FIG. 1.

FIG. 21 is a flowchart summarizing a second exemplary method for fabricating the TFT array substrate of FIG. 10.

FIG. 22 is a schematic, side cross-sectional view of part of a conventional TFT array substrate.

FIG. 23 is a flowchart summarizing a method for fabricating the TFT array substrate of FIG. 22.

FIG. 24 is a schematic, side cross-sectional view relating to a step of providing a substrate and forming a gate electrode on the substrate according to the method of FIG. 23.

FIG. 25 is a schematic, side cross-sectional view relating to a step of forming a gate insulating layer on the substrate having the gate electrode according to the method of FIG. 23.

FIG. 26 is a schematic, side cross-sectional view relating to a step of forming an a-Si layer on the gate insulating layer according to the method of FIG. 23.

FIG. 27 is a schematic, side cross-sectional view relating to a step of forming a heavily doped a-Si layer on the a-Si layer according to the method of FIG. 23.

FIG. 28 is a schematic, side cross-sectional view relating to a step of forming a source electrode and a drain electrode on the gate insulating layer and the heavily doped a-Si layer according to the method of FIG. 23.

FIG. 29 is a schematic, side cross-sectional view relating to a step of forming a passivation layer on the source/drain electrodes and the gate insulating layer according to the method of FIG. 23.

### DETAILED DESCRIPTION OF PREFERRED EMBODIMENTS

Referring to FIG. 1, a thin film transistor (TFT) array substrate 200 according to a first embodiment of the present invention is shown. The TFT array substrate 200 includes a substrate 210, a gate electrode 220 formed on the substrate 210, a gate insulating layer 230 formed on the substrate 210 having the gate electrode 220, a lightly doped amorphous silicon (a-Si) layer 241, an a-Si layer 241 and a heavily doped a-Si layer 243 sequentially formed on the gate insulating layer 230, a source electrode 251 and a drain electrode 252 formed on the gate insulating layer 230 and the heavily doped a-Si layer 243, and a passivation layer 260 formed on the gate insulating layer 230, the source electrode 251 and the drain electrode 252.

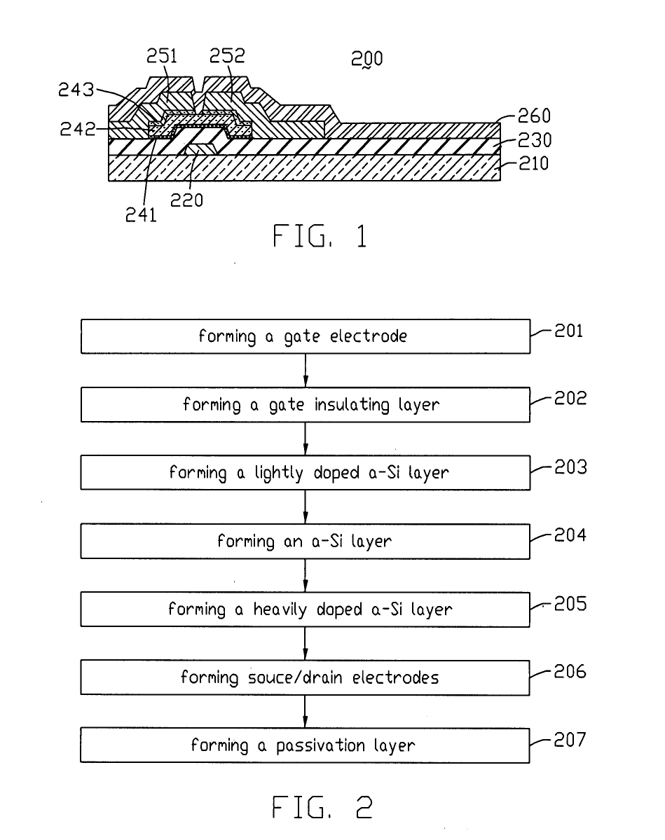

Referring to FIG. 2, this is a flowchart summarizing a first exemplary method for fabricating the TFT array substrate 200. For simplicity, the flowchart and the following description are couched in terms that relate to the part of the TFT array substrate 200 shown in FIG. 2. The method includes: step 201, forming a gate electrode; step 202, forming a gate insulating layer; step 203, forming a lightly doped a-Si layer; step 204, forming an a-Si layer; step 205, forming a heavily doped a-Si layer; step 206, forming source/drain electrodes; and step 207, forming a passivation layer.

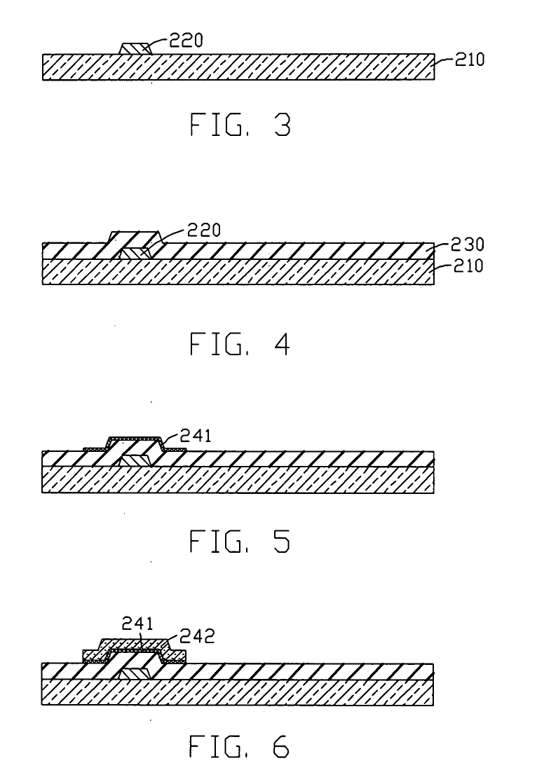

In step 201, referring to FIG. 3, an insulating substrate 210 is provided. The substrate 210 may be made from glass or quartz. A gate metal layer is formed on the substrate 210 by a chemical vapor deposition (CVD) process or a physical vapor deposition (PVD) process. A first photo-resist layer is formed on the gate metal layer. A photo-mask and ultraviolet radiation are provided to expose the first photo-resist layer. The exposed first photo-resist layer is developed, thereby forming a first photo-resist pattern. Using the first photo-resist pattern as a mask, the gate metal layer is etched, thereby forming the gate electrode 220. The first photo-resist pattern is then removed, and the substrate 210 is cleaned and dried. The gate electrode 220 may be made from material including any one or more items selected from the group consisting of aluminum (Al), molybdenum (Mo), titanium (Ti), copper (Cu), chromium (Cr), and tantalum (Ta).

In step 202, referring to FIG. 4, a gate insulating layer 230 is deposited on the substrate 210 having the gate electrode 220 by a CVD process. The gate insulating layer 230 can be made from silicon nitride (SiNₓ) or silicon oxide (SiO₂).

In step 203, referring to FIG. 5, a lightly doped a-Si layer 241 is formed on the gate insulating layer 220 by a CVD process and a vapor phase doping process. A thickness of the lightly doped a-Si layer 241 is less than 60 nanometers. Doped impurities of the lightly doped a-Si layer 241 can be phosphorus (P) ions or arsenic (As) ions.

In step 204, referring to FIG. 6, an a-Si layer 242 is formed on the lightly doped a-Si layer 241 by a CVD process.

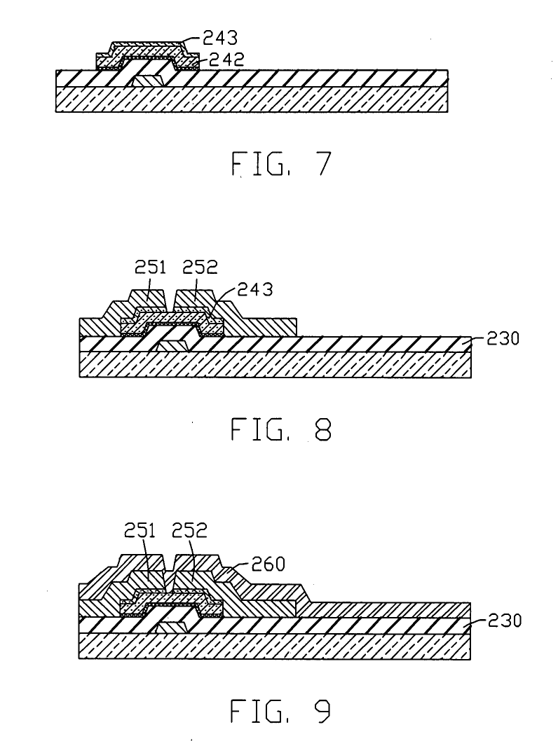

In step 205, referring to FIG. 7, a heavily doped a-Si layer 243 is formed on the a-Si layer 242 by a CVD process, a vapor phase doping process, and a photo-mask process. The heavily doped a-Si layer 243 serves as a buffer layer. In an alternative embodiment, the buffer layer can be omitted.

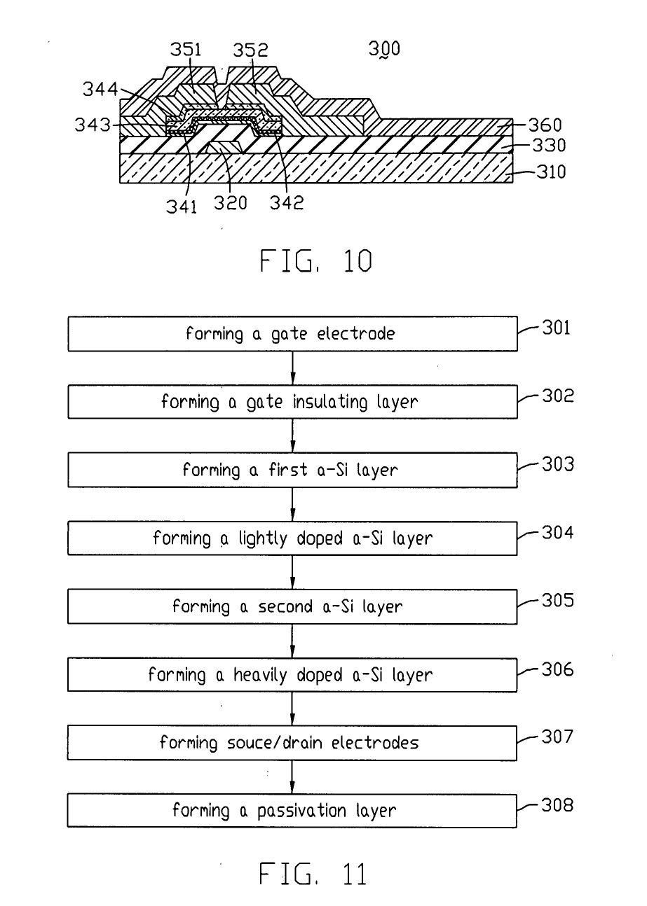

In step 206, referring to FIG. 8, a source/drain metal layer and a second photo-resist layer are sequentially formed on the gate insulating layer 230 and the heavily doped a-Si layer 243. The second photo-resist layer is exposed through a second photo-mask, and is then developed. The source/drain metal layer is etched using the developed second photo-resist layer as a mask, thereby forming a source electrode 251 and a drain electrode 252. The residual second photo-resist layer is then removed.

In step 207, referring to FIG. 9, a passivation layer 260 is formed on the gate insulating layer 230 and the source/drain electrodes 251, 252.

Because a TFT of the TFT array substrate 200 includes a lightly doped a-Si layer 241, which is located between the gate insulating layer 230 and the a-Si layer 242, a consistency and mobility of electrons is increased. When a negative voltage is applied between the gate electrode 220 and the source electrode 251, the increased electron consistency and mobility can block or recombine holes in the a-Si layer 242. This results in a low leakage current.

Referring to FIG. 10, a TFT array substrate 300 according to a second embodiment of the present invention is shown. The TFT array substrate 300 includes a substrate 310, a gate electrode 320 formed on the substrate 310, a gate insulating layer 330 formed on the substrate 310 having the gate electrode 320, a first a-Si layer 341 formed on the gate insulating layer 330, a lightly doped a-Si layer 342 formed on the first a-Si layer 341, a second a-Si layer 343 formed on the lightly doped a-Si layer 342, a heavily doped a-Si layer 344 formed on the second a-Si layer 343, a source electrode 351 and a drain electrode 352 formed on the gate insulating layer 330 and the heavily doped a-Si layer 344, and a passivation layer 360 formed on the gate insulating layer 330, the source electrode 351 and the drain electrode 352.

Referring to FIG. 11, this is a flowchart summarizing a first exemplary method for fabricating the TFT array substrate 300. The method includes: step 301, forming a gate electrode; step 302, forming a gate insulating layer; step 303, forming a first a-Si layer; step 304, forming a lightly doped a-Si layer; step 305, forming a second a-Si layer; step 306, forming a heavily doped a-Si layer; and step 307, forming source/drain electrodes; and step 308, forming a passivation layer.

In step 301, referring to FIG. 12, an insulating substrate 310 is provided. The substrate 310 may be made from glass or quartz. A gate metal layer is formed on the substrate 310 by a chemical vapor deposition (CVD) process or a physical vapor deposition (PVD) process. A first photo-resist layer is formed on the gate metal layer. A photo-mask and ultraviolet radiation are provided to expose the first photo-resist layer. The exposed first photo-resist layer is developed, thereby forming a first photo-resist pattern. Using the first photo-resist pattern as a mask, the gate metal layer is etched, thereby forming the gate electrode 320. The first photo-resist pattern is then removed, and the substrate 310 is cleaned and dried. The gate electrode 320 may be made from material including any one or more items selected from the group consisting of aluminum (Al), molybdenum (Mo), titanium (Ti), copper (Cu), chromium (Cr), and tantalum (Ta).

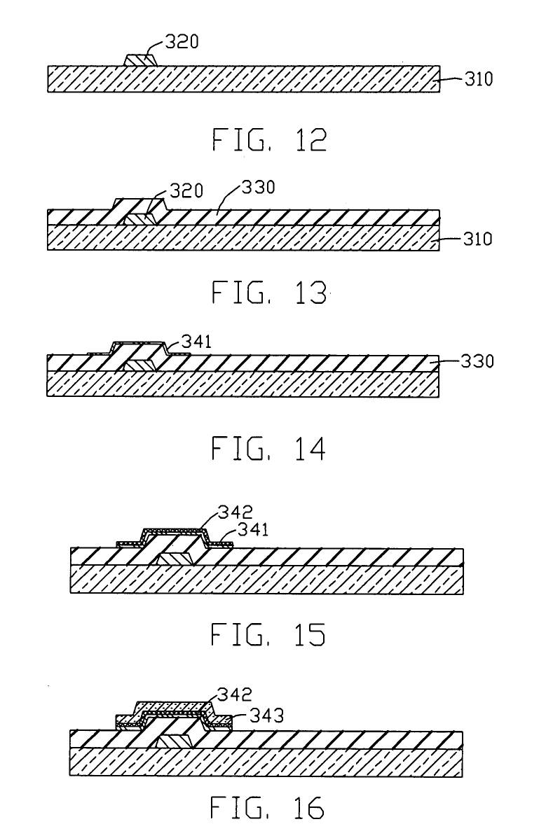

In step 302, referring to FIG. 13, a gate insulating layer 330 is formed on the substrate 310 having the gate electrode 320 by a CVD process. The gate insulating layer 330 can be made from silicon nitride (SiNₓ) or silicon oxide (SiO₂).

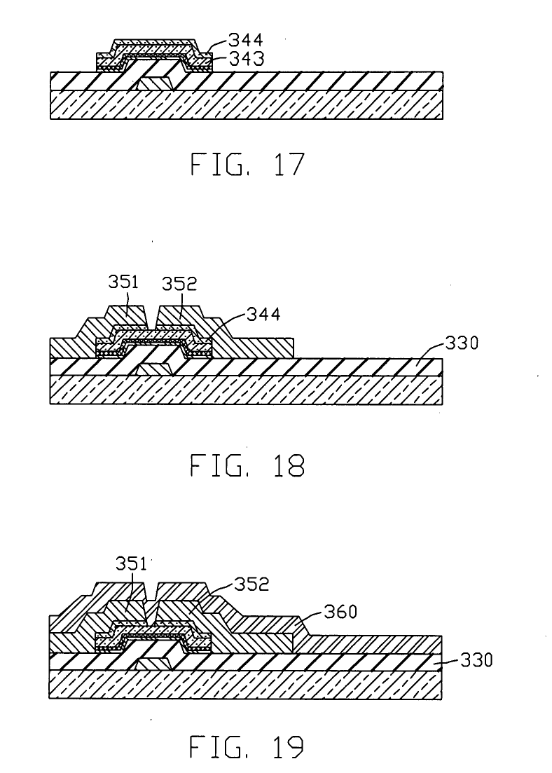

In step 303, referring to FIG. 14, an a-Si layer 341 is deposited on the gate insulating layer 330 by a CVD process.

In step 304, referring to FIG. 15, a lightly doped a-Si layer 342 is formed on the gate insulating layer 330 by a CVD process and a vapor phase doping process. A thickness of the lightly doped a-Si layer 342 is less than 60 nanometers. Doped impurities of the lightly doped a-Si layer 342 can be phosphorus (P) ions or arsenic (As) ions.

In step 305, referring to FIG. 16, a second a-Si layer 343 is deposited on the lightly doped a-Si layer 342 by a CVD process.

In step 306, referring to FIG. 17, a heavily doped a-Si layer 344 is formed on the a-Si layer 343 by a CVD process, a vapor phase doping process, and a photo mask process.

In step 307, referring to FIG. 18, a source/drain metal layer and a second photo-resist layer are sequentially formed on the gate insulating layer 330 having the heavily doped a-Si layer 344. The second photo-resist layer is exposed through a second photo-mask, and is then developed. The source/drain metal layer is etched using the second photo-resist layer as a mask, thereby forming a source electrode 351 and a drain electrode 352. The residual second photo-resist layer is then removed.

In step 308, referring to FIG. 19, a passivation layer 360 is formed on the gate insulating layer 330 having the source/drain electrodes 351, 352 formed thereon.

Because a TFT of the TFT array substrate 300 includes a lightly doped a-Si layer 342, which is between the first a-Si layer 341 and the second a-Si layer 343, a consistency and mobility of electrons is increased. When a negative voltage is applied between the gate electrode 320 and the source electrode 351, the increased electron consistency and mobility can block or recombine holes in the a-Si layers 341, 343. This results in a low leakage current.

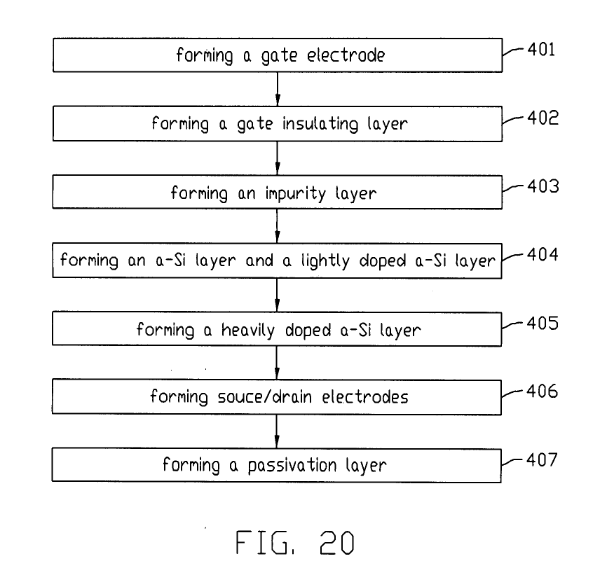

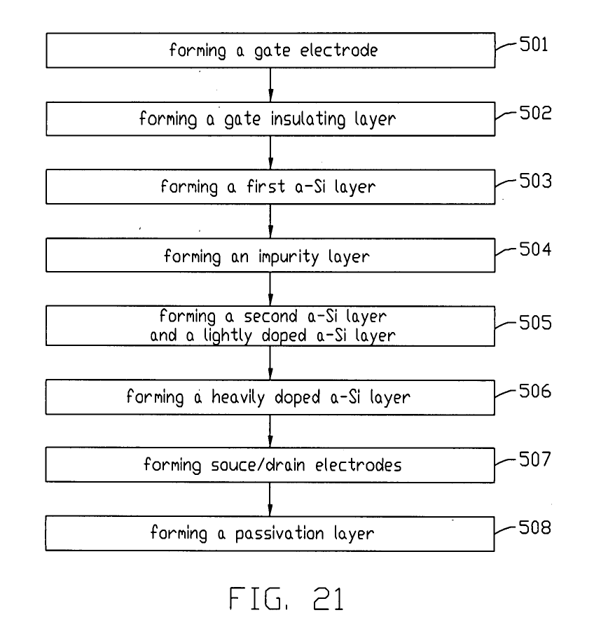

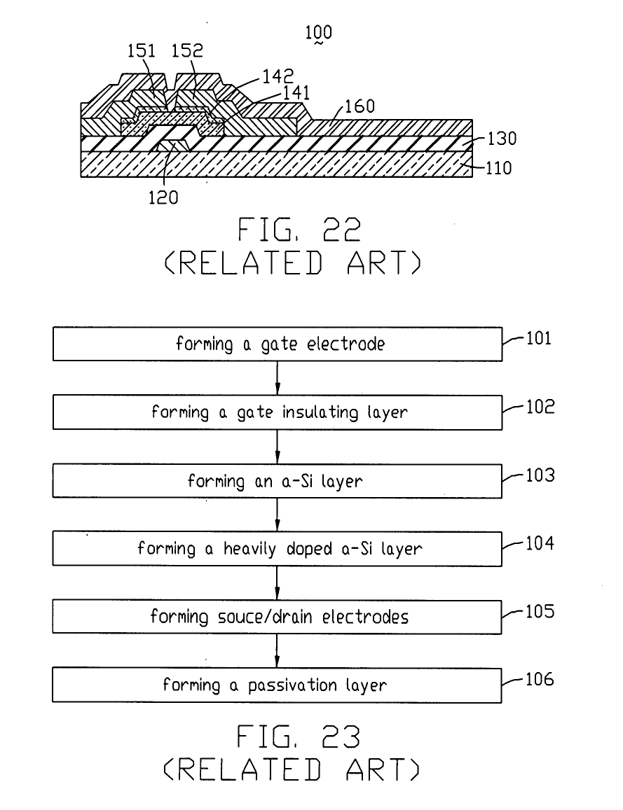

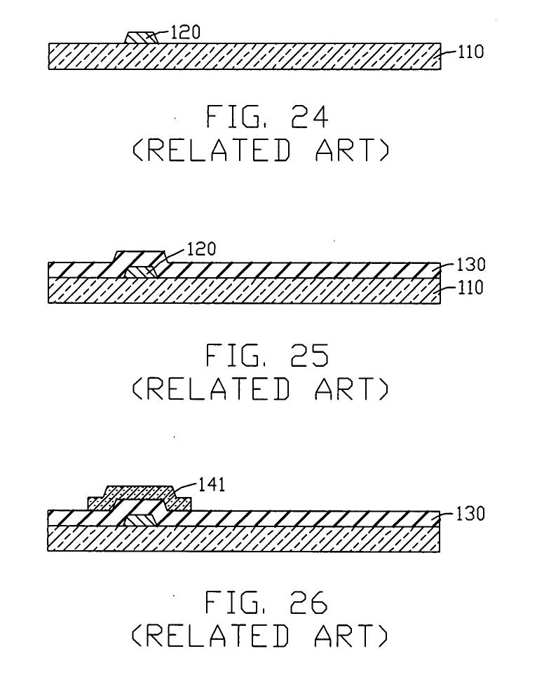

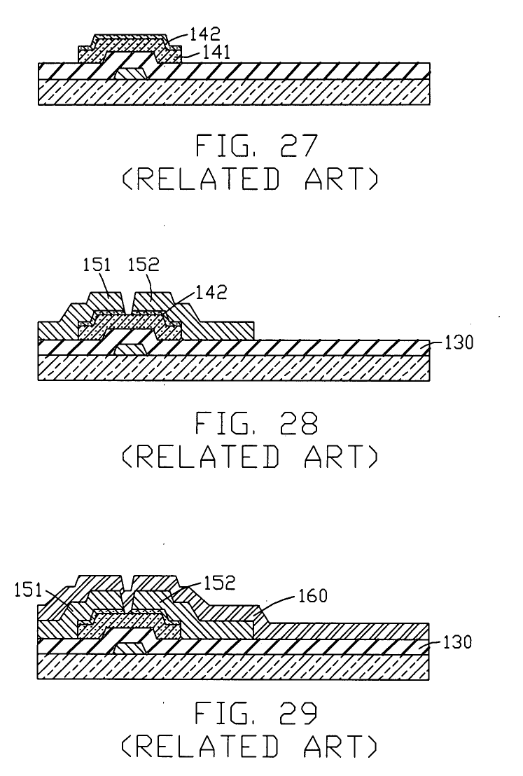

Further and/or alternative embodiment may include the following. Referring to FIG. 20, this is a flowchart summarizing a second exemplary method for fabricating the TFT array substrate 200. The method includes: step 401, forming a gate electrode; step 402, forming a gate insulating layer; step 403, forming an impurity layer; step 404, forming an a-Si layer, and a lightly doped a-Si layer; step 405, forming a heavily doped a-Si layer; step 406, forming source/drain electrodes; and step 407, forming a passivation layer. In step 404, the lightly doped a-Si layer is formed by a natural diffusion process of the impurity layer toward the a-Si layer.

Referring to FIG. 21, this is a flowchart summarizing a second exemplary method for fabricating the TFT array substrate 300. The method includes: step 501, forming a gate electrode; step 502, forming a gate insulating layer; step 503, forming a first a-Si layer; step 504, forming an impurity layer; step 505, forming a second a-Si layer, and a lightly doped a-Si layer; step 506, forming a heavily doped a-Si layer; step 507, forming source/drain electrodes; and step 508, forming a passivation layer. In step 505, the lightly doped a-Si layer is formed by a natural diffusion process of the impurity layer toward the first a-Si layer and the second a-Si layer.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A thin film transistor (TFT) array substrate comprising:
a substrate;
a gate electrode disposed on the substrate;
a gate insulating layer disposed on the substrate having the gate electrode;
a lightly doped amorphous silicon (a-Si) layer disposed on the gate insulating layer;
a first a-Si layer disposed on the lightly doped a-Si layer; and
a source electrode and a drain electrode disposed on the gate insulating layer and the a-Si layer.

2. The TFT array substrate as claimed in claim 1, wherein a thickness of the lightly doped a-Si layer is less than 60 nanometers.

3. The TFT array substrate as claimed in claim 1, wherein impurities of the lightly doped a-Si layer are selected from the group consisting of phosphorus ions and arsenic ions.

4. The TFT array substrate as claimed in claim 1, further comprising a heavily doped a-Si layer disposed between the a-Si layer and the source and drain electrodes.

5. The TFT array substrate as claimed in claim 4, further comprising a passivation formed on the source electrode and the drain electrode.

6. The TFT array substrate as claimed in claim 1, further comprising a second a-Si layer disposed between the gate insulating layer and the lightly doped a-Si layer.

7. The TFT array substrate as claimed in claim 6, wherein a thickness of the second a-Si layer is less than 60 nanometers.

8. The TFT array substrate as claimed in claim 7, further comprising a heavily doped a-Si layer formed between the second a-Si layer and the source and drain electrodes.

9. The TFT array substrate as claimed in claim 1, wherein the substrate is made from glass or quartz.

10. The TFT array substrate as claimed in claim 1, wherein the gate electrode is made from material including any one or more items selected from the group consisting of aluminum (Al), molybdenum (Mo), titanium (Ti), copper (Cu), chromium (Cr), and tantalum (Ta).

11. The TFT array substrate as claimed in claim 1, wherein the gate insulating layer is made from silicon nitride (SiNₓ) or silicon oxide (SiO₂).

12. The TFT array substrate as claimed in claim 1, wherein the source electrode and the drain electrode are made from material including any one or more items selected from the group consisting of aluminum (Al), molybdenum (Mo), titanium (Ti), copper (Cu), chromium (Cr), and tantalum (Ta).

13. A method for fabricating a thin film transistor (TFT) array substrate, the method comprising:
forming a gate electrode on a substrate;
forming a gate insulating layer on the substrate having the gate electrode;
forming a lightly doped amorphous silicon (a-Si) layer on the gate insulating layer;
forming an a-Si layer on the lightly doped a-Si layer; and
forming a source electrode and a drain electrode on the gate insulating layer having the a-Si layer and the lightly doped a-Si layer.

14. The method as claimed in claim 15, wherein the lightly doped a-Si layer is formed by a chemical vapor deposition (CVD) process and a vapor phase doping process.

15. The method as claimed in claim 15, wherein a thickness of the lightly doped a-Si layer is less than 60 nanometers.

16. The method as claimed in claim 15, further comprising a passivation formed on the source electrode and the drain electrode.

17. The method as claimed in claim 15, wherein impurities of the lightly doped a-Si layer are selected from the group consisting of phosphorus ions and arsenic ions.

18. The method as claimed in claim 15, wherein the gate electrode is made from material including any one or more items selected from the group consisting of aluminum (Al), molybdenum (Mo), titanium (Ti), copper (Cu), chromium (Cr), and tantalum (Ta).

19. A method for fabricating a thin film transistor (TFT) array substrate, the method comprising:
forming a gate electrode on a substrate;
forming a gate insulating layer on the substrate having the gate electrode;
forming a first amorphous silicon (a-Si) layer on the gate insulating layer;
forming a lightly doped a-Si layer on the first a-Si layer;
forming a second a-Si layer on the lightly doped a-Si layer;
forming a heavily doped a-Si layer on the second a-Si layer; and
forming a source electrode and a drain electrode on the gate insulating layer having the a-Si layer and the lightly doped a-Si layer.
